(19) United States
(12) Patent Application Publication
(10) Pub. No.: US 2008/0295327 A1
(43) Pub. Date: Dec. 4, 2008

(54) FLEXIBLE CIRCUIT

(75) Inventors: Ellen O. Aeling, St. Paul, MN (US); Michael A. Mels, Stillwater, MN (US); Byron M. Jackson, Forest Lake, MN (US); John R. David, Stillwater, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/756,905

(22) Filed: Jun. 1, 2007

(51) Int. Cl. H05K 3/10

(52) U.S. Cl. 29/832

(57) ABSTRACT

The present application is directed to a method of producing a multilayer circuit. The method comprises providing a first electrically insulating layer comprising apertures through the layer and bonding the first electrically insulating layer with a first conductive layer. The first conductive layer is bonded to the first electrically insulating layer in register to the apertures in the electrically insulating layer and the multilayer circuit is produced at a sustained rate.

In another embodiment, the method comprises providing a second electrically insulating layer and bonding the second electrically insulating layer with the first conductive layer opposite the first electrically insulating layer.

### FIELD

The present application is directed to circuits, for example flexible circuits.

### BACKGROUND

Illumination devices that use circuitry and light management devices are known in the art in numerous applications. Such devices include a light source, and electrical circuit to power the light source and some light management device, such as a reflector or a diffuser to direct light produced by the light source in a desired manner. Such devices may be used, in particular, to attempt to provide illumination with minimal space utilization particularly in the case of thin light guides or light management devices. Known light devices and fixtures used primarily for providing illumination, however, typically utilize bulky housings containing lighting devices such as incandescent light bulb fixtures or similar lighting devices. In particular, applications, such as signs, channel letters and displays, for instance, these known illumination devices utilize a relatively large amount of space.

Lighting devices which employ a circuit substrate may be a fiberglass substrate patterned with copper circuits and mounting holes for components. Such rigid circuit boards, known as FR4 circuit boards, are made to be stiff and rigid by design. Therefore, they are not suitable to mounting onto surfaces that are not flat. Flexible circuits exist, and are typically made of patterned copper on films such as those sold under the tradename KAPTON polyimide films. These circuits offer the benefit of flexibility, but suffer from higher manufacturing costs. In addition, these circuits are typically made by a step and repeat patterning process. Such a process provides a great deal of difficulty in aligning features on the layers and also in making connections between layers. Therefore, such a process is expensive and high maintenance.

### SUMMARY

In one embodiment, the present application is directed to a method of producing a multilayer circuit. The method comprises providing a first electrically insulating layer comprising apertures through the layer and bonding the first electrically insulating layer with a first conductive layer. The first conductive layer is bonded to the first electrically insulating layer in register to the apertures in the electrically insulating layer and the multilayer circuit is produced at a sustained rate.

In another embodiment, the method comprises providing a second electrically insulating layer and bonding the second electrically insulating layer with the first conductive layer opposite the first electrically insulating layer.

### BRIEF DESCRIPTION OF THE DRAWINGS

FIG. 1 is view of a process according to an embodiment of the present application.

FIG. 2 is a perspective exploded view of another example of a disclosed illumination device.

FIG. 3 illustrates an exploded cross section of the device of FIG. 2 through section line 3-3.

### DETAILED DESCRIPTION

### Method

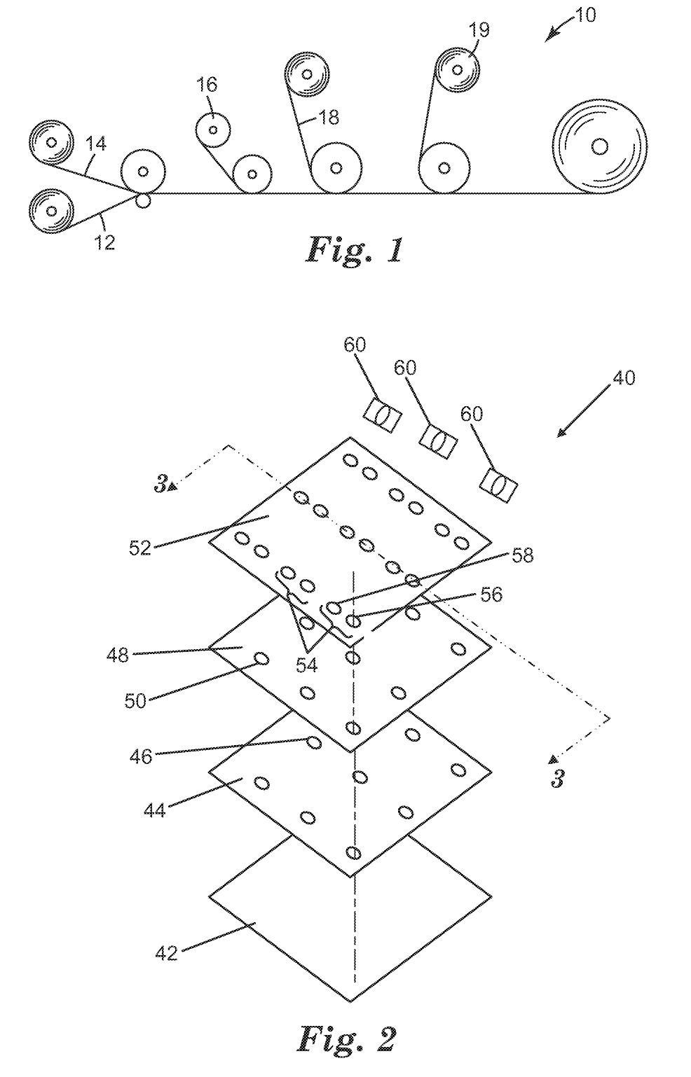

The present application is directed to a multilayer flexible circuit. The circuit is capable of delivering an electric current. The method comprises providing an electrically insulating layer. The electrically insulating layer is bonded to a conductive layer. The layers may be bonded by a permanent bond or may be removable from each other. The connection may be made by a number of methods. In some embodiments, the connection is made by a mechanical process. That is, the bond is formed between two separate layers, and the conductive layer is not chemically deposited onto the electrically insulating layer. For example, a lamination process or joining the electrically insulating layer and the conductive layer together with an adhesive. FIG. 1 illustrates an embodiment of the present method. In FIG. 1, the process 10 comprises an electrically insulating layer 12. The insulating layer 12 is then bonded with a conductive layer 14.

The method of the present application is performed at a sustained rate. A sustained rate, for the purpose of the present application, is defined that a section of the circuit (MINIMUM LENGTH??), during any phase in manufacture, is moving at a constant speed. For example, at each step in the method, the electrically insulating layer and the conductive layer move at the same rate as the resulting multilayer circuit containing those sections of electrically insulating layer and conductive layer.

In some embodiments, the electrically insulating layer is perforated prior to connecting the layer with the conductive layer. The perforations form apertures in the electrically insulating layer. The apertures may be arranged on the electrically insulating layer in an orderly pattern or in a random pattern. Subsequent layers on the multilayer circuit are then registered with the apertures on the electrically conductive layer. For the purpose of the present application, an item is in registry with another item when is has the correct alignment or positioning with respect to the other item.

An electrically insulating layer is non-conductive. The electrically insulating layer is generally a flexible substrate. In certain embodiments, the electrically insulating layer is also thermally insulating. In other embodiments, the electrically insulating layer is thermally conductive. In some embodiments, the flexible substrate is a polymer film, for example a light enhancement film.

The conductive layer is generally a self supporting layer, and may be formed from any material that is conductive. Generally, the conductive layer is formed from a material that is can be prepared into a sheet.

The conductive layer may be continuous or discontinuous. In embodiments where the conductive layer is discontinuous, the circuit is broken at the point the conductive layer is disrupted. The conductive layer may be a full sheet or in a pattern. Examples of suitable patterns include a grid pattern, a series string pattern, series/parallel pattern, a series of parallel patterns, a parallel array of strings, or combinations thereof.

The adhesive used in the present invention may be any adhesive suitable to connect the electrically insulating layer to the conductive layer. In some embodiments, the adhesive is a pressure sensitive adhesive. In some embodiments, the adhesive is a heat processed adhesive, for example a hot melt adhesive.

In many embodiments, the multilayer circuit comprises a second electrically insulating layer and a second conductive layer. FIG. 1 shows the second electrically insulating layer 16 and the second conductive layer 18. Additionally, the method may comprise a bottom film 19 covering the multilayer circuit. The bottom film may be an additional electrically insulating layer or a separate polymer film, or a combination of both.

FIG. 2 illustrates an embodiment of a multilayer circuit resulting from the process of the present application. Specific embodiments of the multilayer circuit made by the process of the present application can be found, for example, in copending application U.S. Ser. No. ______, claiming priority from U.S. Application No. 60/826,245 (Attorney Docket Number 60609US011), incorporated by reference herein. A first conductive layer 42 may consist of a metal foil, such as a copper foil or other suitable conductor fashionable as a sheet or layer. Disposed on the first conductor layer 42 is a first electrical insulating or non-conductive layer 44. In some embodiments, another electrical insulating or non-conducting layer can be disposed beneath the first conductive layer 42, sandwiching the conductive layer 42 between the two non-conductive layers. The first electrical insulator layer 44 includes one or more apertures 46 through the layer. The first electrical insulator layer 44 may consist of any known electrical insulator or dielectric capable of being fashioned as a sheet or layer, or a light reflective layer, as described above. Additionally, layer 44 may include an adhesive on one or both sides for adhering layer 44 to adjoining layers such as first conductive layer 42.

In the embodiment shown in FIG. 2, device 40 further includes a second conductive layer 48 disposed on the upper surface of first electrical insulating layer 44. Additional, multiple layers may be added within the scope of the present application. Second conductive layer 48 includes one or more apertures 50 through the layer and may consist of a metal foil, such as a copper foil or other suitable conductor fashionable as a sheet or layer. Apertures 50 and 46 are configured to align or be in register with each other. Finally, device 40 includes film layer 52. Film layer 52 may consist of a reflective material or have some other light manipulative property, as the light reflective films described above. Layer 52 includes one or more pairs of apertures 54, each pair 54 having first 56 and second 58 apertures. First aperture 56 aligns with or is in register with holes 46 and 50 in the first conductive layer 44 and the second conductive layer 50, respectively. FIG. 2 shows this alignment with vertical dashed line. Thus, an illumination source having at least two terminals, such as an LED with anode and cathode terminals, disposed on the upper surface of layer 52 may make electrical contact with first conductive layer 42 through apertures 56, 50, and 46. The other terminal of the light illumination source can be in electrical communication with the second conductive layer 48 through apertures 58. In some embodiments, layer 52 includes a single large aperture that replaces each pair 54 of first 56 and second 58 apertures.

Device 40 also includes one or more light or illumination sources 60, which may be one or more light emitting diodes (LEDs) having two contacts (i.e., an anode and cathode), but are not limited to such. Examples of LEDs that may be used include LEDs of various colors such as white, red, orange, amber, yellow, green, blue, purple, or any other color of LEDs known in the art. The LEDs may also be of types that emit multiple colors dependent on whether forward or reverse biased, or of types that emit infrared or ultraviolet light. Furthermore, the LEDs may include various types of packaged LEDs or bare LED die, as well as monolithic circuit board type devices or a configuration using circuit leads or wires.

It is noted that either the upper surface of second conductor layer 48 or the bottom surface of the optical film layer 52 may include an adhesive to affix layers 48 and 52 together. Additionally, the layers of assembled device 40 are laminated together to achieve a unitary construction.

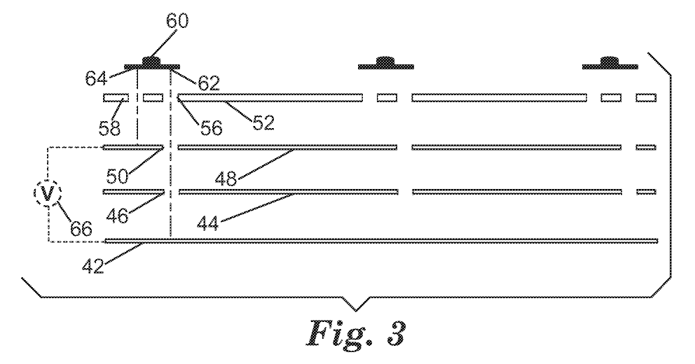

FIG. 3 illustrates an exploded cross section of the device of FIG. 2 through section line 3-3 extending the entire vertical cross section distance of device 40. As illustrated, a portion 62 of an illumination source 60 is positioned over aligned apertures 56, 50, and 46 to allow electrical communication between portion 62 and the first conductor layer 42. Another portion 64 of the illumination devices 60 is positioned over aperture 58, affording electrical communication between portion 64 and second conductive layer 48. Accordingly, a source of power, such as a voltage source 66, may then be connected across the first and second conductor layers 42 and 48, as illustrated, to supply power to drive the illumination source 60.

As noted above, in some embodiments, the light source is a compact light emitting diode (LED). In this regard, “LED” refers to a diode that emits light, whether visible, ultraviolet, or infrared. It includes incoherent encased or encapsulated semiconductor devices marketed as “LED”, whether of the conventional or super radiant variety. If the LED emits non-visible light such as ultraviolet light, and in some cases where it emits visible light, it is packaged to include a phosphor (or it may illuminate a remotely disposed phosphor) to convert short wavelength light to longer wavelength visible light, in some cases yielding a device that emits white light. An “LED die” is an LED in its most basic form, i.e., in the form of an individual component or chip made by semiconductor processing procedures. The component or chip can include electrical contacts suitable for application of power to energize the device. The individual layers and other functional elements of the component or chip are typically formed on the wafer scale, and the finished wafer can then be diced into individual piece parts to yield a multiplicity of LED dies. More discussion of packaged LEDs, including forward-emitting and side-emitting LEDs, is provided herein.

If desired, other light sources such as linear cold cathode fluorescent lamps (CCFLs) or hot cathode fluorescent lamps (HCFLs) can be used instead of or in addition to discrete LED sources as illumination sources for the disclosed backlights. In addition, hybrid systems such as, for example, (CCFL/LED), including cool white and warm white, CCFL/HCFL, such as those that emit different spectra, may be used. The combinations of light emitters may vary widely, and include LEDs and CCFLs, and pluralities such as, for example, multiple CCFLs, multiple CCFLs of different colors, and LEDs and CCFLs.

In some embodiments, the light source includes light sources capable of producing light having different peak wavelengths or colors (e.g., an array of red, green, and blue LEDs).

In some embodiments, a transparent film, or other light controlling film, is bonded to the multilayer circuit over the electronic component of light source. This transparent film then protects the light source from external damage. In other embodiments, a translucent film is bonded to the multilayer circuit over the electronic component of light source. This translucent film then protects the light source from external damage and diffuses the light that is emitted to improve uniformity of the light.

The method disclosed in the present application may be run in a continuous process. That is, the length of the multilayer circuit is limited only by the length of the feed film for the layers. The method may also be set for a roll to roll continuous process. Such a method may run at speeds in excess of 300 feet per minute.

In additional embodiments, the multilayer circuit is cut from its roll form to form smaller circuits.

Various modifications and alterations of the present invention will become apparent to those skilled in the art without departing from the spirit and scope of the invention.

What is claimed is:

1. A method of producing a multilayer circuit comprising:
providing a first electrically insulating layer having at least one aperture defined through the layer; and
bonding the first electrically insulating layer with a first conductive layer;
wherein the first conductive layer is bonded to the first electrically insulating layer in register to the apertures in the electrically insulating layer and the multilayer circuit is produced at a sustained rate.

2. The method of claim 1 wherein the conductive layer is bonded to the first electrically insulating layer via a mechanical process.

3. The method of claim 1 comprising providing a first adhesive layer disposed on a first surface of the first insulating layer between the first electrically insulating layer and the first conductive layer.

4. The method of claim 1 wherein the first conductive layer is discontinuous.

5. The method of claim 4 wherein the first conductive layer is in a pattern.

6. The method of claim 5 wherein the pattern is a grid pattern, a series string pattern, a series or parallel pattern, or a series of repeating circuits.

7. The method of claim 1 comprising cutting the multilayer circuit into smaller circuits.

8. The method of claim 1 comprising
providing a second electrically insulating layer; and
bonding the second electrically insulating layer with the first conductive layer opposite the first electrically insulating layer.

9. The method of claim 8 comprising providing a second adhesive layer disposed on a first surface of the second insulating layer opposite the first conductive layer.

10. The method of claim 9 comprising connecting the second adhesive layer with a second conductive layer opposite the second insulating layer.

11. The method of claim 8 wherein the first conductive layer is continuous.

12. The method of claim 11 wherein the first conductive layer is in a pattern.

13. The method of claim 12 wherein the pattern is a grid pattern.

14. The method of claim 8 wherein the first conductive layer is discontinuous.

15. The method of claim 14 wherein the first conductive layer is in a pattern.

16. The method of claim 15 wherein the pattern is a grid pattern.

17. The method of claim 8 wherein the second conductive layer is continuous.

18. The method of claim 17 wherein the second conductive layer is in a pattern.

19. The method of claim 18 wherein the pattern is a grid pattern.

20. The method of claim 8 wherein the second conductive layer is discontinuous.

21. The method of claim 20 wherein the second conductive layer is in a pattern.

22. The method of claim 21 wherein the pattern is a grid pattern, a series string pattern, a series or parallel pattern, or a series of repeating circuits.

23. The method of claim 1 wherein the first electrically insulating layer is perforated to form apertures arranged in a pattern prior to contacting the first electrically insulating layer to the first conductive layer.

24. The method of claim 23 wherein the multilayer circuit is registered to the pattern in the first electrically insulating layer.

25. The method of claim 1 wherein the first electrically insulating layer is a flexible substrate.

26. The method of claim 1 wherein the first electrically insulating layer is a polymer film.

27. The method of claim 8 wherein the second electrically insulating layer is a flexible substrate.

28. The method of claim 8 wherein the second electrically insulating layer is a polymer film.

29. The method of claim 2 wherein the adhesive is a pressure sensitive adhesive.

30. The method of claim 3 wherein the adhesive is heat activated.

31. The method of claim 1 wherein the first electrically insulating layer is extruded on the first conductive layer.

32. The method of claim 1 wherein the first electrically insulating layer is adhered to the first conductive layer.

33. The method of claim 32 wherein the first electrically insulating layer is laminated to the first conductive layer.

34. The method of claim 1 comprising placing at least one light source on the multilayer circuit on the first electrically insulating layer, opposite the first conductive layer.

35. The method of claim 34 comprising multiple light sources on the multilayer circuit.

36. The method of claim 35 wherein the multiple light sources are arranged in a pattern.

37. The method of claim 36 wherein the pattern is a regular array.

38. The method of claim 34 wherein the light source is a light emitting diode.

39. The method of claim 8 comprising placing at least one light source on the multilayer circuit.

40. The method of claim 1 comprising attaching an electronic component to the first conductive layer.

41. The method of claim 8 comprising attaching an electronic component to the second conductive layer.

42. The method of claim 1 wherein the method runs as speeds greater than 300 feet per minute.

43. The method of claim 1 wherein the method is continuous.

44. The method of claim 34 comprising attaching a transparent layer or a translucent layer over the light source, opposite the multilayer circuit.

45. The method of claim 39 comprising attaching a transparent layer or a translucent layer over the light source, opposite the multilayer circuit.

46. The method of claim 1 wherein the conductive layer has at least one aperture defined through the conductive layer and positioned to align with the at least one aperture in the electrically insulating layer.
